(19) United States
(12) Patent Application Publication
(10) Pub. No.: US 2014/0362059 A1
(43) Pub. Date: Dec. 11, 2014

(54) THIN FILM TRANSISTOR AND DISPLAY DEVICE USING THE SAME

(71) Applicant: Japan Display Inc., Tokyo (JP)

(72) Inventors: Norihiro UEMURA, Tokyo (JP); Hidekazu MIYAKE, Tokyo (JP); Takeshi NODA, Tokyo (JP); Isao SUZUMURA, Tokyo (JP); Yohei YAMAGUCHI, Tokyo (JP)

(21) Appl. No.: 14/300,257

(22) Filed: Jun. 10, 2014

(30) Foreign Application Priority Data
Jun. 10, 2013 (JP) 2013-121494

(51) Int. Cl. H01L 27/12; G09G 5/00; H01L 29/786

(52) U.S. Cl. CPC H01L 27/1251; H01L 29/7869; H01L 27/1225; G09G 5/00
USPC 345/204; 257/43

(57) ABSTRACT

A thin film transistor includes a drain electrode layer and a source electrode layer that are formed above an oxide semiconductor layer via an insulating film. The drain electrode layer and the source electrode layer are electrically connected with the oxide semiconductor layer via through-holes formed in the insulating film. A first through-hole that electrically connects the drain electrode layer with the oxide semiconductor layer and a second through-hole that electrically connects the source electrode layer with the oxide semiconductor layer each include two or more through-holes that are arranged in parallel in a channel width direction of the thin film transistor. A total width of opening widths of the first or second through-holes in the channel width direction is a channel width of the thin film transistor.

### CROSS-REFERENCE TO RELATED APPLICATION

The present application claims priority from Japanese application JP2013-121494 filed on Jun. 10, 2013, the content of which is hereby incorporated by reference into this application.

### BACKGROUND OF THE INVENTION

1. Field of the Invention

The present invention relates to a thin film transistor and a display device using the same, and more particularly to a thin film transistor using oxide semiconductor for a semiconductor layer in which a channel region is formed.

2. Description of the Related Art

In thin film transistors using oxide semiconductor for a semiconductor layer (hereinafter referred to as oxide thin film transistors), it has been known that a favorable thin film transistor with high mobility can be formed by a process substantially equal to that of a thin film transistor using amorphous silicon or the like for a semiconductor layer. Especially in the oxide thin film transistors in which a semiconductor layer is formed of oxide semiconductor, a so-called bottom-gate type thin film transistor is common in which an oxide semiconductor layer is formed above a gate electrode layer formed on a top surface of an insulating substrate and a source electrode layer and a drain electrode layer (source/drain electrode layer) are formed on a top surface of the oxide semiconductor layer. In the oxide thin film transistor having this configuration, it has been known that an oxide thin film transistor with high mobility and high reliability is formed by forming an insulating film serving as a channel protective layer on the top surface of the oxide semiconductor layer, that is, on a surface thereof on the side where the source/drain electrode layer is formed.

In the formation of a related-art oxide thin film transistor, an oxide semiconductor layer is formed, and then, an insulating film covering a top surface of an insulating substrate is formed so as to also cover the oxide semiconductor layer. Next, through-holes (contact holes) are formed in the insulating film, so that source/drain electrode layer formed on the top surface of the insulating film is electrically connected with the oxide semiconductor layer via the through-holes. In this case, the insulating film formed in a region between the source electrode layer and the drain electrode layer serves as a channel protective layer. Moreover, the length of the through-hole in a channel width direction via which the source electrode layer and the oxide semiconductor layer are connected and the through-hole via which the drain electrode layer and the oxide semiconductor layer are connected, that is, the opening width of the pair of through-holes in the channel width direction is a substantial channel width.

The present inventors have formed a gate scanning circuit of a liquid crystal display device using oxide thin film transistors on a glass substrate. On the other hand, for the individual oxide thin film transistors constituting the gate scanning circuit, a channel width needs to be changed according to an operating capability needed for each of the oxide thin film transistors. However, the present inventors have found a problem in the related-art oxide thin film transistor having the structure described above that when the channel width of the oxide thin film transistor, that is, the opening width of the through-hole in the channel.0 width direction is changed according to an operating capability, the threshold voltage is shifted in the negative direction as the channel width is increased. That is, the present inventors have found a problem that when a gate scanning circuit, a selector circuit, or the like configured using oxide thin film transistors having different channel widths is to be prepared, the circuit does not normally operate because the oxide thin film transistors having different channel widths have different threshold voltages.

On the other hand, JP 2008-034819 A (Patent Document 1) discloses a semiconductor device in which contact holes whose diameters are different between a source region and a drain region are formed in each thin film transistor (TFT) forming a memory cell in a ROM. In the semiconductor device disclosed in Patent Document 1, the contact holes are formed such that the sum of bottom areas of the contact holes formed on the source region side is the same as that of the contact holes formed on the drain region side, and a gate electrode layer and a drain electrode layer are electrically connected with a semiconductor layer (island-like semiconductor film) via the contact holes.

Moreover, JP 2000-357735 A (Patent Document 2) discloses a semiconductor device in which a semiconductor layer made of polysilicon (p-Si) is formed on a substrate composed of an amorphous silicon (a-Si) film and the number of contact holes is reduced to provide a closest packing arrangement. In the semiconductor device disclosed in Patent Document 2, one edge of a gate electrode is extended to the source electrode side of the semiconductor layer, a contact hole through which the surfaces of the gate electrode and the semiconductor layer are exposed is formed, and a source electrode connected to both the semiconductor layer and the gate electrode via the contact hole is formed.

### SUMMARY OF THE INVENTION

However, even when the structure disclosed in FIG. 7 of Patent Document 1 is applied to an oxide thin film transistor, the sums of bottom areas of the contact holes different in diameter between the source region and the drain region need to be the same. That is, even when a gate scanning circuit is configured using the technique disclosed in Patent Document 1, the channel width of thin film transistors constituting the gate scanning circuit needs to be changed according to an operating capability needed for each of the thin film transistors. Accordingly, even when the technique disclosed in Patent Document 1 is used, the sum of bottom areas of the contact holes needs to be set to a bottom area suitable for a needed drive capability of the thin film transistor. Therefore, a gate scanning circuit needs to be formed of thin film transistors having different channel widths, that is, thin film transistors having different threshold voltages, giving rise to a fear that the circuit does not normally operate.

On the other hand, Patent Document 2 discloses a technique in which a data-side driver circuit and a scanning-side driver circuit are formed in a region outside the display area, a so-called picture-frame region. However, it is a technique of reducing the number of contact holes to provide a closest packing arrangement, in which no consideration is taken to a change in threshold voltage associated with the difference in the channel width of the thin film transistor.

The invention has been made in view of the problems, and it is an object of the invention to provide a technique by which it is possible to suppress fluctuations in threshold voltage in oxide thin film transistors having different channel widths and formed on the same insulating substrate.

(1) To solve the problems, a thin film transistor according to an aspect of the invention includes: an oxide semiconductor layer that is formed above a gate electrode layer via a first insulating film; and a drain electrode layer and a source electrode layer that are formed above the oxide semiconductor layer via a second insulating film, wherein the drain electrode layer and the source electrode layer are electrically connected with the oxide semiconductor layer via through-holes formed in the second insulating film arranged between the drain and source electrode layers and the oxide semiconductor layer, the drain electrode layer and the source electrode layer are formed over opposite edge portions of the oxide semiconductor layer, a channel region is formed in a region of the oxide semiconductor layer between the drain electrode layer and the source electrode layer that are electrically connected with the oxide semiconductor layer via the through-holes, a first through-hole that electrically connects the drain electrode layer with the oxide semiconductor layer and a second through-hole that electrically connects the source electrode layer with the oxide semiconductor layer each include two or more through-holes that are arranged in parallel in a channel width direction of the thin film transistor, and a total width of opening widths of the first through-holes or the second through-holes in the channel width direction is a channel width of the thin film transistor.

(2) To solve the problems, a display device according to an aspect of the invention includes a first substrate, the first substrate including, formed thereon, scanning signal lines that extend in an X-direction and are arranged in parallel in a Y-direction and to which a scanning signal is input, video signal lines that extend in the Y-direction and are arranged in parallel in the X-direction and to which a video signal is input, switching thin film transistors each of which is arranged in the vicinity of an intersection between the scanning signal line and the video signal line and controls reading of the video signal in synchronization with the scanning signal, and a driver circuit that generates the scanning signal or/and the video signal, wherein at least the driver circuit is formed of the thin film transistor according to (1), and the thin film transistor includes two or more thin film transistors in which at least the numbers of the first through-holes are different from each other and whose drive capabilities are different from each other.

According to the invention, it is possible to suppress fluctuations in threshold voltage in oxide thin film transistors having different channel widths and formed on the same insulating substrate.

Other advantageous effects of the invention will be apparent from the description of the entire specification.

### BRIEF DESCRIPTION OF THE DRAWINGS

FIGS. 1A and 1B explain a schematic configuration of a thin film transistor of Embodiment 1 of the invention.

FIG. 2 is a plan view of a thin film transistor formed using n unit thin film transistors of Embodiment 1.

FIG. 3 shows a relationship between the number of formed unit thin film transistors of Embodiment 1 and the on-current of the entire thin film transistors.

FIG. 4 is a plan view showing a schematic configuration of a related-art thin film transistor.

FIGS. 5A and 5B explain a schematic configuration of another related-art thin film transistor.

FIGS. 6A and 6B explain a thin film transistor formed using one unit thin film transistor of Embodiment 1.

FIG. 7 shows gate voltage-drain current curves in the thin film transistor of Embodiment 1 of the invention.

FIG. 8 shows gate voltage-drain current curves in the related-art thin film transistor.

FIG. 9 shows a relationship between the channel width and the threshold voltage in the thin film transistor of Embodiment 1 and the related-art thin film transistor.

FIG. 10 is a plan view for explaining an adjacent gap of the unit thin film transistor of Embodiment 1.

FIG. 11 shows the on-current when changing the channel width in an oxide thin film transistor of the invention.

FIGS. 12A, 12B, and 12C explain a method for manufacturing the thin film transistor of Embodiment 1 of the invention.

FIGS. 13D, 13E, and 13F explain the method for manufacturing the thin film transistor of Embodiment 1 of the invention.

FIGS. 14A and 14B explain a schematic configuration of another thin film transistor of Embodiment 1 of the invention.

FIGS. 15A and 15B explain a schematic configuration of a thin film transistor of Embodiment 2 of the invention.

FIG. 16 shows a relationship between the opening width of a through-hole of a unit thin film transistor of Embodiment 2 of the invention and a transistor size in a channel width direction.

FIG. 17 shows a relationship between the opening width of the through-hole of the unit thin film transistor of the invention and the threshold voltage.

FIG. 18 shows a relationship between the opening width of the through-hole of the unit thin film transistor of the invention and an adjacent gap of the through-hole.

FIGS. 19A and 19B explain a schematic configuration of another thin film transistor of Embodiment 2 of the invention.

FIGS. 20A and 20B explain a schematic configuration of a thin film transistor of Embodiment 3 of the invention.

FIG. 21 is a plan view for explaining a schematic configuration of a liquid crystal display device as a display device of Embodiment 4 of the invention.

### DETAILED DESCRIPTION OF THE INVENTION

Hereinafter, embodiments to which the invention is applied will be described with reference to the drawings. In the following description, the same constituent elements are denoted by the same reference and numeral signs, and the repetitive description thereof is omitted. Moreover, X, Y, and Z shown in the drawings indicate an X-axis, a Y-axis, and a Z-axis, respectively.

### Embodiment 1

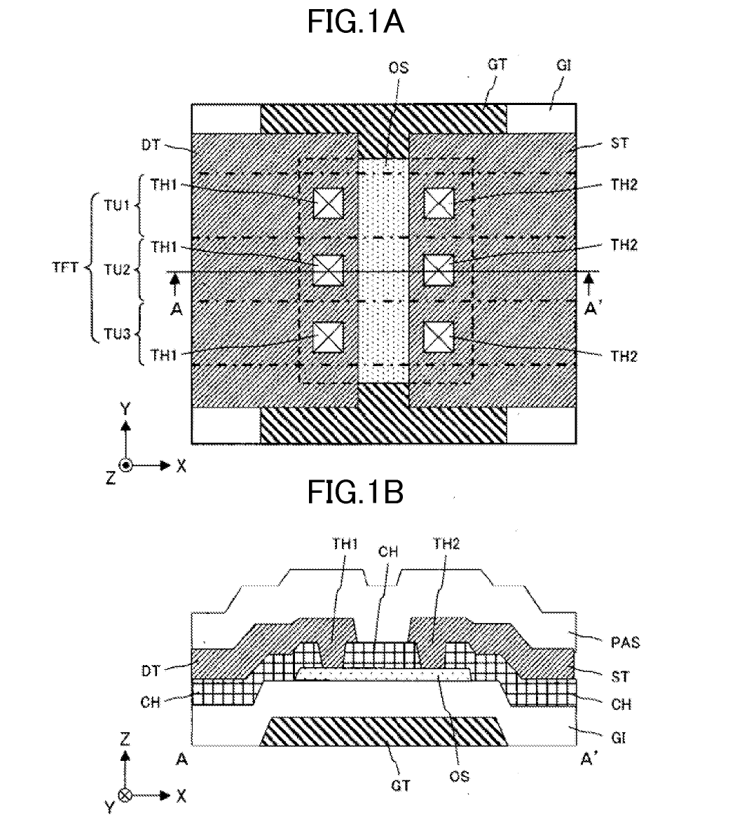

FIGS. 1A and 1B explain a schematic configuration of a thin film transistor of Embodiment 1 of the invention, in which FIG. 1A is a plan view of the thin film transistor of Embodiment 1; and FIG. 1B is a cross-sectional view taken along the line A-A′ shown in FIG. 1A. In the following description, a case will be described in which a thin film transistor of the invention is applied to a display device such as a liquid crystal display device or an organic EL display device. Accordingly, a case will be described in which a light-transmissive glass substrate is used as an insulating substrate. The thin film transistor of the invention can be applied to those other than a display device. In such a case, a non-light-transmissive, well-known insulating substrate may be used as an insulating substrate. In the thin film transistor of Embodiment 1, first and second through-holes TH1 and TH2 are square having the same width in an X-direction and a Y-direction.

As shown in FIG. 1B, in the thin film transistor (oxide thin film transistor) of Embodiment 1 using oxide semiconductor for a semiconductor layer, a gate electrode layer GT composed of a well-known conductive thin film is formed on a surface of an insulating substrate (not shown), and a gate insulating film GI (first insulating film) is formed over a top surface of the insulating substrate (not shown) so as to also cover the gate electrode layer GT. The gate insulating film GI is formed of an insulating film composed of a well-known inorganic material such as a silicon oxide film, a silicon nitride film, or a silicon oxynitride film. The gate insulating film GI may have a stacked structure, which may be obtained by combining any of the insulating films described above with one another, but a layer to be in contact with an oxide semiconductor layer OS is preferably a silicon oxide film. Further, it is preferred that the gate insulating film GI is formed to have a film thickness within a range of from 80 nm to 2000 nm. However, the gate insulating film GI may be formed to have an appropriate, optimum film thickness in view of a dielectric withstand voltage, capacitance, or the like.

The oxide semiconductor layer OS, which is island-like, is formed on a top surface of the gate insulating film GI so as to overlap the gate electrode layer GT. The oxide semiconductor layer OS is an In—Ga—Zn—O-based oxide semiconductor including, as main components, elements of indium, gallium, zinc, and oxygen, which is referred to also as IGZO film. In addition to the In—Ga—Zn—O-based oxide semiconductor, In—Al—Zn—O-based, In—Sn—Zn—O-based, In—Zn—O-based, In—Sn—O-based, Zn—O-based, or Sn—O-based oxide semiconductor may be used. It is preferred that the oxide semiconductor layer OS has a film thickness within a range of from 30 nm to 500 nm. However, the film thickness is appropriately adjusted in accordance with purposes such as increasing the film thickness when used for a device that needs a large amount of current.

A channel protective layer (second insulating film) CH that is composed of a silicon oxide film as a well-known insulating film material and covers a top surface of the insulating substrate (not shown), that is, the top surface of the gate insulating film GI is formed on a top surface of the oxide semiconductor layer OS so as to also cover the oxide semiconductor layer OS. A pair of through-holes (contact holes or holes) TH1 and TH2 that reach the surface of the oxide semiconductor layer OS are formed in the channel protective layer CH at portions arranged on the oxide semiconductor layer OS (an overlapped region portion where the channel protective layer CH overlaps the oxide semiconductor layer OS). The pair of through-holes TH1 and TH2 are formed along a side portion of the overlapped region.

In the first through-hole TH1 as one of the through-holes (through-hole on the left side in FIG. 1B), a metal thin film serving as a drain electrode layer DT is formed so as to cover the first through-hole TH1. In the second through-hole TH2 as the other through-hole (through-hole on the right side in FIG. 1B), a metal thin film serving as a source electrode layer ST is formed so as to cover the second through-hole TH2.

In this case, some oxide semiconductors provide an ohmic contact even when a conductive film such as a metal thin film is formed on the surface of the oxide semiconductor, while others need a well-known contact layer for realizing an ohmic contact similarly to silicon semiconductor. Accordingly, when the oxide semiconductor layer OS is formed of the oxide semiconductor that does not need a contact layer, the oxide semiconductor layer OS exposed through the first and second through-holes TH1 and TH2 serves as contact regions relative to the drain electrode layer DT and the source electrode layer ST. On the other hand, when the oxide semiconductor layer OS is formed of the oxide semiconductor that needs a contact layer, the contact layer is formed using a well-known technique. Due to this, similarly to the case where the oxide semiconductor layer OS is formed of the oxide semiconductor that does not need a contact layer, the regions of the oxide semiconductor layer OS exposed through the first and second through-holes TH1 and TH2 serve as the contact regions relative to the drain electrode layer DT and the source electrode layer ST. By adopting the configuration described above, the contact regions (not shown) corresponding to the first and second through-holes TH1 and TH2 are formed in the oxide semiconductor layer OS. With this configuration, the drain electrode layer DT and the source electrode layer ST are electrically connected with the oxide semiconductor layer OS via the first through-hole TH1 and the second through-hole TH2, respectively. The drain electrode layer DT, the source electrode layer ST, and the gate electrode layer GT of the oxide thin film transistor TFT of Embodiment 1 are formed of an element selected from aluminum, molybdenum, chromium, copper, tungsten, titanium, zirconium, tantalum, silver, and manganese, or an alloy combining these elements. Moreover, a stacked structure obtained by stacking aluminum on titanium or interposing aluminum between upper and lower titanium layers may be adopted.

A protecting insulating film serving as a passivation layer PAS and composed of a well-known inorganic material is formed on the drain electrode layer DT and the source electrode layer ST so as to cover the insulating substrate (not shown), that is, the channel protective layer CH and also cover the drain electrode layer DT and the source electrode layer ST. The passivation layer PAS is formed of an insulating film such as a silicon oxide film, a silicon nitride film, or a silicon oxynitride film. The passivation layer PAS may have a stacked structure, which may be obtained by combining any of the insulating films described above with one another.

Especially in the oxide thin film transistor of Embodiment 1, as is apparent from FIG. 1A, three through-holes (the first through-holes TH1) arranged in parallel in the Y-direction are formed in a region where the drain electrode layer DT and the oxide semiconductor layer OS that form one thin film transistor TFT overlap each other. Similarly, three through-holes (the second through-holes TH2) arranged in parallel in the Y-direction are formed in a region where the source electrode layer ST and the oxide semiconductor layer OS overlap each other. In FIG. 1A, edges of the oxide semiconductor layer OS arranged below the drain electrode layer DT and the source electrode layer ST are formed up to portions indicated by the dashed lines in the drawing.

In this case, the same oxide semiconductor layer OS is exposed through the three first through-holes TH1 and the three second through-holes TH2, and the same drain electrode layer DT is electrically connected to the same oxide semiconductor layer OS via each of the three first through-holes TH1. Similarly, the source electrode layer ST is electrically connected to the same oxide semiconductor layer OS via each of the three second through-holes TH2. Further, the gate electrode layer GT formed below the oxide semiconductor layer OS and the oxide semiconductor layer OS are formed so as to overlap each other in a plan view via the gate insulating layer GI.

Accordingly, in the configuration of Embodiment 1, an oxide thin film transistor (unit thin film transistor) TU1 is formed in which the drain electrode layer DT and the source electrode layer ST that are connected to the oxide semiconductor layer OS via the first through-hole TH1 and the second through-hole TH2 on the upper stage in FIG. 1A, and the gate electrode layer GT arranged to overlap the oxide semiconductor layer OS via the gate insulating film GI serve as electrodes. Similarly, unit thin film transistors TU2 and TU3 are formed in which the drain electrode layer DT and the source electrode layer ST that are connected to the oxide semiconductor layer OS via the first and second through-holes TH1 and TH2 on the middle or lower stage in FIG. 1A, and the gate electrode layer GT serve as electrodes. As will be described in detail later, the three unit thin film transistors TU1 to TU3 have the same electrical characteristics.

In the three unit thin film transistors TU1 to TU3, in this case, since the drain electrode layer DT, the source electrode layer ST, and the gate electrode layer GT are formed of the same conductive thin film, the first to third unit thin film transistors TU1 to TU3 are connected in parallel. That is, one oxide thin film transistor TFT of Embodiment 1 is formed of the three unit thin film transistors TU1 to TU3 connected in parallel. In this case, the unit thin film transistors TU1 to TU3 are configured using, as a basic unit, the first through-hole TH1 and the second through-hole TH2 as a pair of through-holes that are formed in the channel protective layer CH for electrically connecting the drain electrode layer DT and the source electrode layer ST to the oxide semiconductor layer OS. Therefore, a channel region of each of the unit thin film transistors TU1 to TU3 is formed in the oxide semiconductor layer OS in a region between the pair of first through-hole TH1 and second through-hole TH2 indicated by the dash-dotted lines in FIG. 1A.

As described above, in the configuration of the oxide thin film transistor TFT of Embodiment 1, one oxide thin film transistor TFT is formed of the three unit thin film transistors TU1 to TU3 arranged in parallel in the Y-direction and indicated by the dashed lines in FIG. 1A. In this case, the numbers of the first through-holes TH1 and the second through-holes TH2 that are formed respectively in opposite edge regions of the same oxide semiconductor layer OS are the same so that the first to third unit thin film transistors TU1 to TU3 have substantially the same electrical characteristics. Moreover, an opening width of the first through-hole TH1 and an opening width of the second through-hole TH2 are formed to be substantially the same (especially exposed areas of the oxide semiconductor layer OS exposed respectively through the through-holes TH1 and TH2 are substantially the same). Further, the first through-holes TH1 and the second through-holes TH2 are arranged in parallel at the same interval in the same Y-direction, and gaps (channel lengths) in the X-direction each between the first through-hole TH1 and the second through-hole TH2 that form each of the unit thin film transistors TU1 to TU3 are formed to have the same gap.

With the configuration described above, the unit thin film transistors TU1 to TU3 constituting the oxide thin film transistor TFT of Embodiment 1 have substantially the same channel length and the same channel width, and the unit thin film transistors TU1 to TU3 also have substantially the same electrical characteristics. In the configuration of the oxide thin film transistor TFT of Embodiment 1, a direction connecting the pair of first through-hole TH1 and second through-hole TH2 together (a channel length direction or the X-direction) is orthogonal to a direction in which the first through-holes TH1 and the second through-holes TH2 are arranged in parallel (a channel width direction or the Y-direction) so that the unit thin film transistors TU1 to TU3 have substantially the same characteristics. However, the invention is not limited to this configuration.

In FIGS. 1A and 1B, only the through-holes TH1 and TH2 formed in the channel protective layer CH according to the invention are illustrated, and other through-holes for connecting the drain electrode layer DT, the source electrode layer ST, and the gate electrode layer GT to signal lines (not shown) are omitted. In the specification, the conductive thin film arranged on the left side in the drawings is the drain electrode layer DT, while the conductive thin film arranged on the right side in the drawings is the source electrode layer ST. However, the invention is not limited to this arrangement. The drain electrode layer DT and the source electrode layer ST may be arranged on either side.

### (Relationship Between Channel Width and Number of Unit Thin Film Transistors)

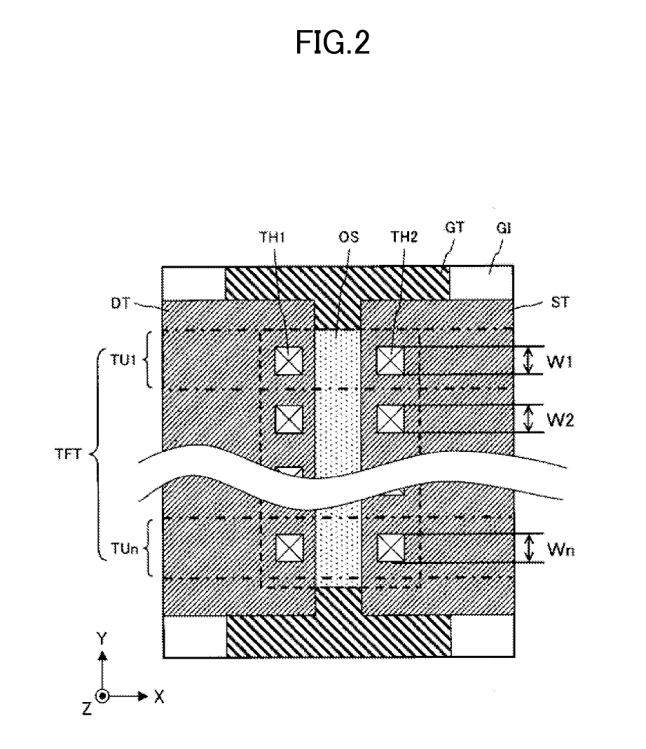

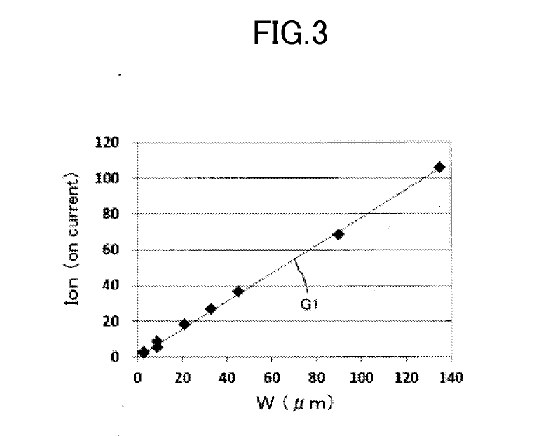

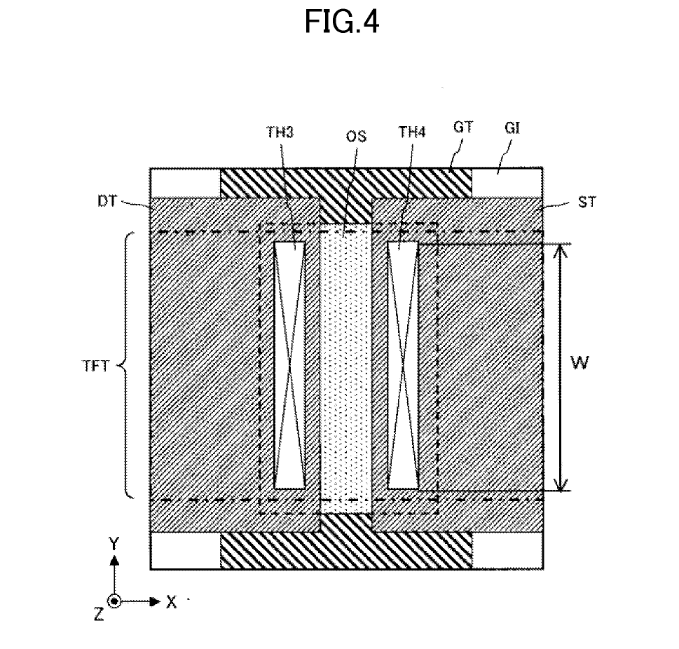

FIG. 2 is a plan view of an oxide thin film transistor formed using n unit thin film transistors of Embodiment 1. FIG. 3 shows a relationship between the number of formed unit thin film transistors of Embodiment 1 and the on-current of the entire oxide thin film transistor. FIG. 4 is a plan view showing a schematic configuration of a related-art oxide thin film transistor. Hereinafter, advantageous effects of the oxide thin film transistor of Embodiment 1 will be described in detail.

The oxide thin film transistor TFT shown in FIG. 2 is configured such that n (where n is a natural number of 1 or more, while the case where n=1 will be described in detail later) unit thin film transistors TU1 to TUn are arranged in parallel in the Y-direction (channel width direction of the unit thin film transistor TU), and that the unit thin film transistors TU1 to TUn are connected in parallel. That is, the first to nth n unit thin film transistors TU1 to TUn constitute one thin film transistor TFT in which the drain electrode layer DT and the source electrode layer ST are connected to the oxide semiconductor layer OS via n first through-holes TH1 and n second through-holes TH2 whose opening widths W1 to Wn in the Y-direction (channel width direction of the unit thin film transistor TU) are the same in size. For example, in the first unit thin film transistor TU1 illustrated on the uppermost stage in FIG. 2, the widths of both the first through-hole TH1 and the second through-hole TH2 in the Y-direction are the opening width W1. With this configuration, corresponding to the first and second through-holes TH1 and TH2, regions of the width W1 in the Y-direction in the oxide semiconductor layer OS, that is, regions of the oxide semiconductor layer OS exposed through the first and second through-holes TH1 and TH2 serve as contact regions, and a channel region is formed in a region between the contact regions. Therefore, the unit thin film transistor TU1 is formed in which the opening width W1 as the width of a connection region between the oxide semiconductor layer OS and the drain and source electrode layers DT and ST is a channel width. Similarly, also in the nth unit thin film transistor TUn illustrated on the lowermost stage in FIG. 2, the widths of both the first through-hole TH1 and the second through-hole TH2 in the Y-direction are the opening width Wn (=W1), and therefore, the unit thin film transistor TUn having the channel width Wn (=W1) is formed.

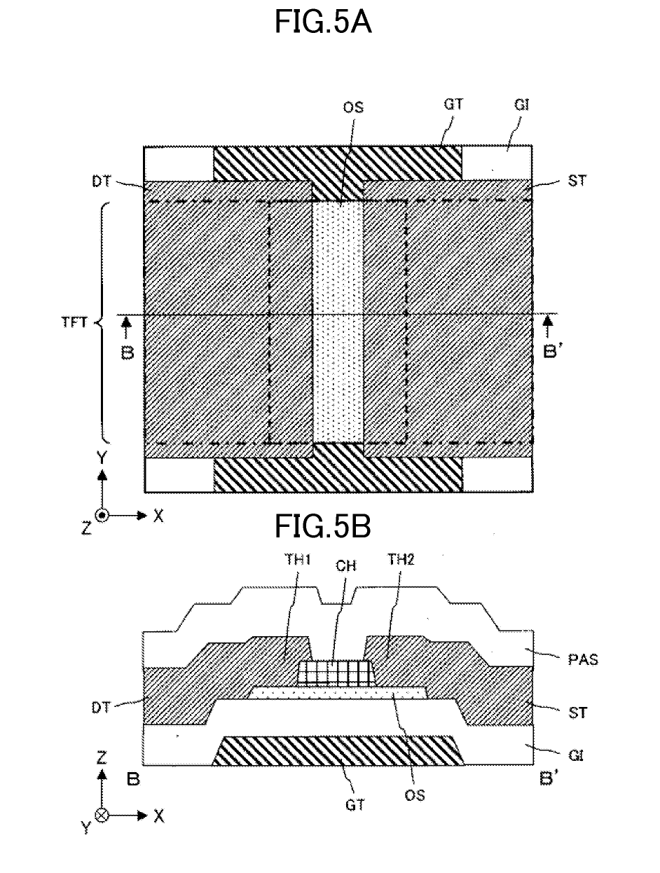

Therefore, in the oxide thin film transistor TFT of Embodiment 1 shown in FIG. 2, when the sum of opening widths of the first through-holes TH1 or the second through-holes TH2 in the Y-direction, that is, the sum of channel widths is W, the relationship of W=W1+W2+ . . . +Wn=n×W1 is satisfied. Therefore, the oxide thin film transistor TFT of Embodiment 1 shown in FIG. 2 has the same drive capability as that of a thin film transistor formed to have the channel width W. That is, the drive capability is the same as that of the related-art oxide thin film transistor shown in FIG. 4 in which each of one through-hole TH3 that connects the drain electrode layer DT with the oxide semiconductor layer OS and one through-hole TH4 that connects the source electrode layer ST with the oxide semiconductor layer OS is formed to have an opening width of the width W in the Y-direction. Examples of related-art oxide thin film transistors include, as shown in FIGS. 5A and 5B, an oxide thin film transistor in which the drain electrode layer DT and the source electrode layer ST are formed so as to be in direct contact with the surface of the oxide semiconductor layer OS and the channel protective layer CH is formed between the drain electrode layer DT and the source electrode layer ST in a plan view.

Accordingly, as is apparent from the line G1 shown in FIG. 3, also in the oxide thin film transistor TFT of Embodiment 1, the on-current of the thin film transistor TFT is increased in proportion to an increase in the total opening width W, that is, the number of the unit thin film transistors TU connected in parallel. As a result, the on-current of the oxide thin film transistor TFT of Embodiment 1 can be estimated from the total opening width W. In FIG. 3, the horizontal axis represents the total opening width (the sum of opening widths) W of the second through-holes TH2 in the channel width direction when changing the variable n as the number of unit thin film transistors, while the vertical axis represents the measured value of the on-current of one oxide thin film transistor TFT formed of n unit thin film transistors. The size (opening width) W1, W2, . . . , or Wn of the second through-hole TH2 (including the first through-hole TH1) in the channel width direction, which determines the channel width of each of the unit thin film transistors TU1 to TUn, is any opening width set in advance. Moreover, the on-current is expressed in any units. Further, FIG. 3 shows the on-current obtained when the opening width of the first through-hole TH1 in the channel width direction is the same as the opening width W1, W2, . . . , or Wn of the second through-hole TH2.

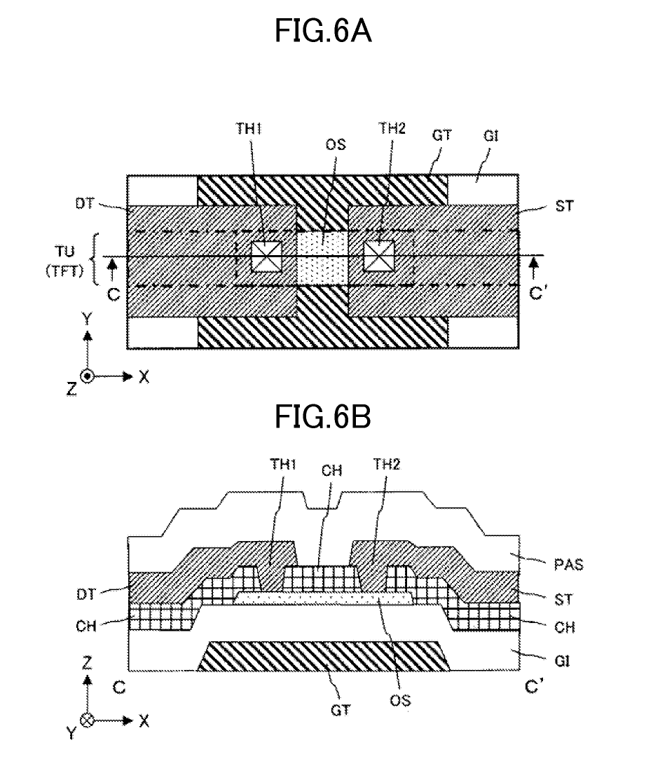

In the above-described configuration of the oxide thin film transistor shown in FIG. 1A to 2, one oxide thin film transistor TFT is formed of a plurality of unit thin film transistors TU. However, the invention is not limited to this configuration. For example, when one unit thin film transistor TU has a sufficient drive capability, one oxide thin film transistor TFT is formed of one unit thin film transistor TU (corresponding to the case where n=1) as shown in FIG. 6A. Also in this case, as is apparent from FIG. 6B, which is a cross-sectional view taken along the line C-C′ in FIG. 6A, a stacked structure of thin film layers is the same as the structure shown in FIG. 1B. Therefore, for an oxide thin film transistor TFT that does not need too much current, the configuration using the oxide thin film transistor TFT formed of one unit thin film transistor TU is effective.

As described above, the unit thin film transistors TU are combined in parallel, so that even when a gate scanning circuit, a selector circuit, or the like is formed using a plurality of oxide thin film transistors TFT having different drive capabilities and different sizes on the same insulating substrate as that of a pixel electrode or the like, fluctuations in threshold voltage can be suppressed to realize favorable switching.

However, for the opening widths W1 to Wn of the first through-holes TH1 and the second through-holes TH2 of the unit thin film transistors TU1 to TUn, there is, for example, the following method. The opening width W1 is determined according to the minimum operating capability (drive capability) for the oxide thin film transistor TFT when constituting a gate scanning circuit, a selector circuit, or the like. Next, for the oxide thin film transistor TFT that needs the minimum operating capability, the oxide thin film transistor TFT is formed of a single unit thin film transistor TU. Other oxide thin film transistors TFT that need a greater drive capability is appropriately formed of a plurality of unit thin film transistors TU according to the needed drive capability. In this case, in addition to the advantageous effect described above, it is possible to suppress an increase in the occupied area of the oxide thin film transistor TFT associated with configuring a driver circuit such as a gate scanning circuit or a selector circuit using the oxide thin film transistor TFT of Embodiment 1.

Moreover, the oxide thin film transistor TFT that needs the minimum operating capability may be formed of two or more plurality of unit thin film transistors TU. With this configuration, the number of unit thin film transistors TU that determine the drive capability of the oxide thin film transistor TFT, that is, an increment or decrement of the channel width W can be made small. As a result, when the other oxide thin film transistors TFT are formed, it is possible to obtain a special advantageous effect that the oxide thin film transistor TFT having a drive capability closer to the needed drive capability can be formed. The reason is as follows. Especially in the configuration of Embodiment 1, since one thin film transistor TFT is formed of the n unit thin film transistors TU1 to TUn connected in parallel, the opening width of the oxide thin film transistor TFT has a discrete value corresponding to the number of unit thin film transistors TU. Accordingly, in the configuration of Embodiment 1, the drive capabilities of a plurality of oxide thin film transistors TFT formed on the same insulating substrate are properly grasped, and the unit thin film transistors TU are formed corresponding to the drive capabilities. Therefore, it is possible to suppress an increase in the occupied area of the transistor element associated with the use of the oxide thin film transistor TFT of Embodiment 1.

Moreover, in the oxide thin film transistor TFT of Embodiment 1, the oxide semiconductor layer OS can be used for a semiconductor layer. Therefore, it becomes easy to improve reliability and realize high mobility as the characteristics of the oxide thin film transistor TFT. That is, it is possible to form a thin film transistor having a great drive capability even with the same occupied area as that of an amorphous silicon thin film transistor. Moreover, when a circuit is formed using the oxide thin film transistor TFT of Embodiment 1, it is also possible to obtain an advantageous effect that a circuit area can be made smaller than that of an amorphous silicon thin film transistor.

The oxide thin film transistor TFT of Embodiment 1 has a bottom-gate type transistor structure, but the invention is not limited to a bottom-gate type oxide thin film transistor. The invention can also be applied to an oxide thin film transistor having another structure such as a top-gate type. Further, the invention can also be applied to an oxide thin film transistor having a structure in which the source electrode layer ST and the drain electrode layer DT are arranged on the side below the oxide semiconductor layer OS, that is, on the insulating substrate side.

### DESCRIPTION OF ADVANTAGEOUS EFFECT

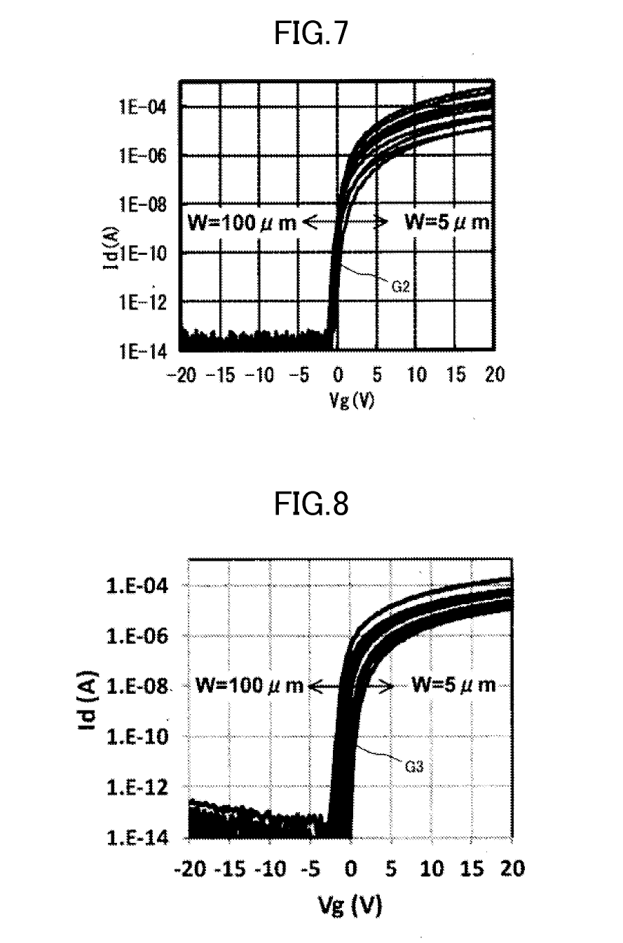

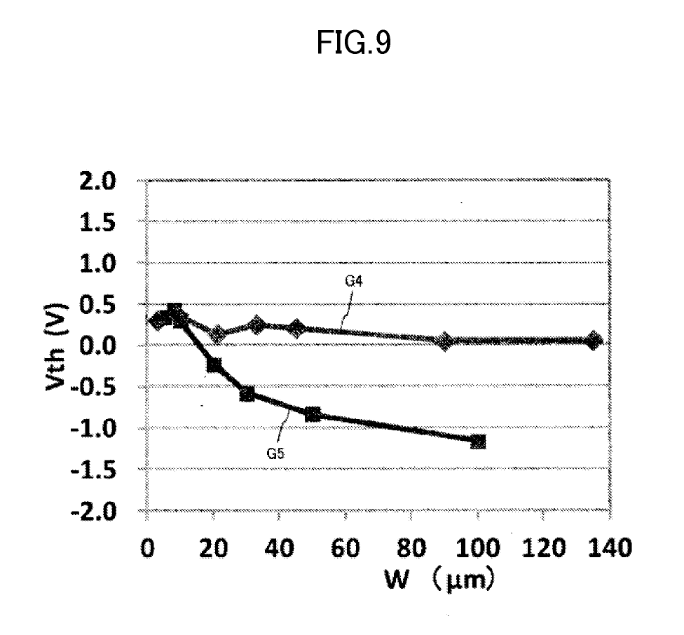

FIG. 7 shows gate voltage-drain current curves (Vg-Id curves) in the thin film transistor of Embodiment 1 of the invention. FIG. 8 shows gate voltage-drain current curves (Vg-Id curves) in a related-art thin film transistor. FIG. 9 shows a relationship between the channel width and the threshold voltage in the thin film transistor TFT of Embodiment 1 and the related-art thin film transistor. On the curves G2 and G3 shown in FIGS. 7 and 8, a gate voltage Vg at which a drain current Id is a predetermined current is a threshold voltage Vth. Hereinafter, the effect of fluctuations in threshold voltage in the oxide thin film transistor TFT of Embodiment 1 formed on the same insulating substrate and having different channel widths will be described in detail based on FIGS. 7 to 9.

The curves G2 in FIG. 7 are displayed by superimposing the gate voltage-drain current curves (Vg-Id curves) in different oxide thin film transistors TFT each having a total opening width W of from 5 μm to 100 μm, which are obtained while changing the number of unit thin film transistors TU that form one thin film transistor TFT. The curves G3 in FIG. 8 are displayed by superimposing the Vg-Id curves in the related-art oxide thin film transistor shown in FIG. 4 whose second through-hole TH4 has an opening width (also the first through-hole TH3 has the same opening width) W of from 5 μm to 100 μm. However, the curves G2 and G3 of the Vg-Id curves shown in FIGS. 7 and 8 are obtained with the oxide thin film transistors having the same channel length.

As is apparent from FIG. 8, in the related-art oxide thin film transistor, a non-saturation region (for example, a region where the drain current Id changes from 1×10-13 to 1×10-7 ampere (A)) as a region where the drain current Id greatly changes in proportion to a change in the gate voltage Vg is formed, and then, a saturation region where the drain current Id is constant for a change in the gate voltage Vg is formed. In this case, as is apparent from FIG. 8, in the related-art oxide thin film transistor TFT, the non-saturation region is greatly shifted (changed) to the negative voltage side associated with an increase in the opening width of the first and second through-holes TH3 and TH4, that is, the channel width W. That is, the threshold voltage Vth is also greatly shifted to the negative voltage side.

In contrast to this, as is apparent from FIG. 7, in the oxide thin film transistor TFT of Embodiment 1, the shift of the non-saturation region to the negative voltage side can be greatly suppressed as the total opening width W increases, that is, the number of unit thin film transistors TU increases. Therefore, it is apparent that the non-saturation region is not substantially shifted. That is, in the oxide thin film transistor TFT of Embodiment 1, even when the total opening width W is increased, and therefore, the substantial channel width W is increased, the shift of the non-saturation region to the negative voltage side can be greatly suppressed. As a result, the shift of the non-saturation region to the negative voltage side, that is, the shift of the threshold voltage Vth to the negative voltage side can be greatly suppressed.

As is especially apparent from the line G4 shown in FIG. 9, in the oxide thin film transistor TFT of Embodiment 1 of the invention, the threshold voltage Vth is about 0.25V (volt) due to this suppression effect when the substantial channel width W that is determined by the total opening width W falls within a range of from 5 to 50 μm. Also when the substantial channel width W falls within a range of from 50 to 140 μm, the threshold voltage Vth is 0V (zero volt) or more. Therefore, it is apparent that the threshold voltage Vth is not almost changed. Therefore, it is possible to greatly suppress a change in the threshold voltage Vth associated with an increase in the channel width W, that is, associated with an increase in the drive capability of the oxide thin film transistor TFT. It is considered that the suppression effect on fluctuations in the threshold voltage Vth in the oxide thin film transistor TFT of Embodiment 1 is provided because in the unit thin film transistors TU constituting the oxide thin film transistor TFT of Embodiment 1, the size of the opening width (length) of individual through-holes (the first and second through-holes TH1 and TH2) in the channel width direction is constant, and therefore, the size of the channel width is also constant.

On the other hand, as is apparent from the line G5 shown in FIG. 9, in the related-art oxide thin film transistor, the threshold voltage Vth is greatly shifted (depleted) to the negative voltage side from 0.25V to −0.6V when the opening width of the first and second through-holes TH3 and TH4, that is, the channel width W falls within a range of from about 5 to 30 μm. Also when the channel width W falls within a range of from 30 to 100 μm, only the rate of change in the threshold voltage Vth is slightly reduced, and as a result, the threshold voltage Vth is greatly shifted from −0.6V to −1.2V.

### (Adjacent Gap Between Unit Thin Film Transistors)

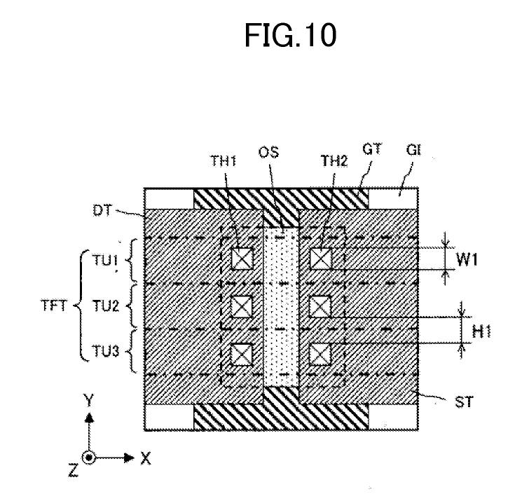

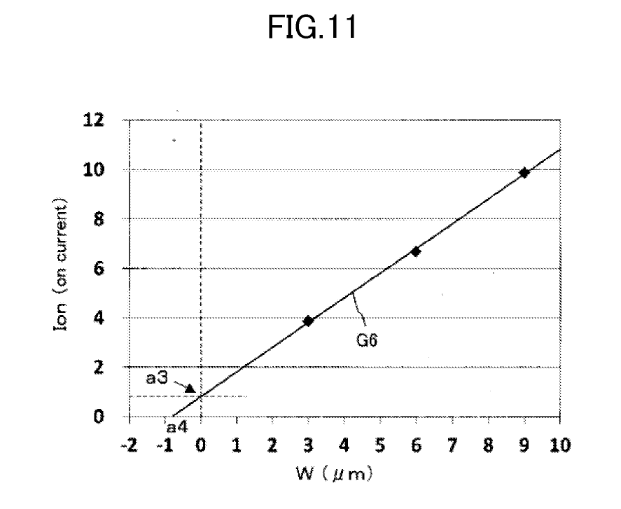

FIG. 10 is a plan view for explaining an adjacent gap between unit thin film transistors. FIG. 11 shows the on-current when changing the channel width in the oxide thin film transistor TFT of the invention. Hereinafter, a relationship between the on-current and the channel width W in a region where the channel width W is small will be described based on FIGS. 10 and 11. The oxide thin film transistor TFT shown in FIG. 10 has the same configuration as that shown in FIGS. 1A and 1B. The channel width (total channel width) W of the oxide thin film transistor TFT shown in FIG. 11 is the total channel width W of one oxide thin film transistor TFT formed by connecting in parallel one to three unit thin film transistors TU having a channel width W1 of 3 μm, and FIG. 11 is obtained by measuring the dependency of an on-current Ion on the total channel width W.

As is apparent from the description and the like described above, the on-current Ion apparently increases in proportion to the number of unit thin film transistors TU, that is, to the channel width W in the following cases: where the oxide thin film transistor TFT is formed of only one unit thin film transistor TU1 having the channel width W1=3 μm (when W=3 μm); where one oxide thin film transistor TFT is formed of two unit thin film transistors TU1 and TU2 having the channel width W1=W2=3 μm (when W=6 μm); and where one oxide thin film transistor TFT is formed of three unit thin film transistors TU1, TU2, and TU3 having the channel width W1=W2=W3=3 μm (when W=9 μm).

In this case, as shown in FIG. 11, the on-current Ion of the oxide thin film transistor TFT when W=3, 6, and 9 μm increases along the linear line G6. Therefore, when the line G6 is extrapolated to W=0 μm for estimating the case where the channel width W of the oxide thin film transistor TFT is reduced, it is found that a small amount of on-current flows even when W=0 μm as is apparent from the position a3 shown in the drawing. Further, as is apparent from the position a4 at which the line G6 is extrapolated to Ion=0 (zero), the value of the channel width W at which the on-current Ion is 0 (zero) is about −0.8 μm. This shows that a small amount of current flows beyond the length (opening width) W1 of the first through-hole TH1 and the second through-hole TH2 in the channel width direction. This result shows that if it is assumed that the current flowing beyond the length flows equally on both sides of the channel region, the current flows beyond the first through-hole TH1 and the second through-hole TH2 on both sides by about 0.4 μm.

From the facts described above, it is found that the first and second through-holes TH1 and TH2 adjacent to each other need to be formed with a certain gap on both sides (in the adjacent direction of the unit thin film transistors TU1 to TU3) of the first and second through-holes TH1 and TH2. That is, the contact region as a region where the drain electrode layer DT or the source electrode layer ST is connected with the oxide semiconductor layer OS needs to be arranged with a certain gap.

As a result of investigation of the size of this gap, it is found that when each gap (adjacent gap) H1 between the adjacent first through-holes TH 1 and between the adjacent second through-holes TH2 shown in FIG. 10 is 2 μm or less, the depletion of the threshold voltage Vth, that is, the shift of the threshold voltage Vth in the negative direction is caused.

Accordingly, when the length (opening width) W1 of the first through-hole TH1 and the second through-hole TH2 in the channel width direction is 3 μm, it is preferable to form a gap of 1 μm or more on both sides of each of the unit thin film transistors TU1 to TU3 (both sides of each of the first through-holes TH1 arranged adjacent to each other and each of the second through-holes TH2 arranged adjacent to each other), that is, to set the adjacent gap H1 in the Y-direction (channel width direction) to be 2 μm or more.

### (Manufacturing Method)

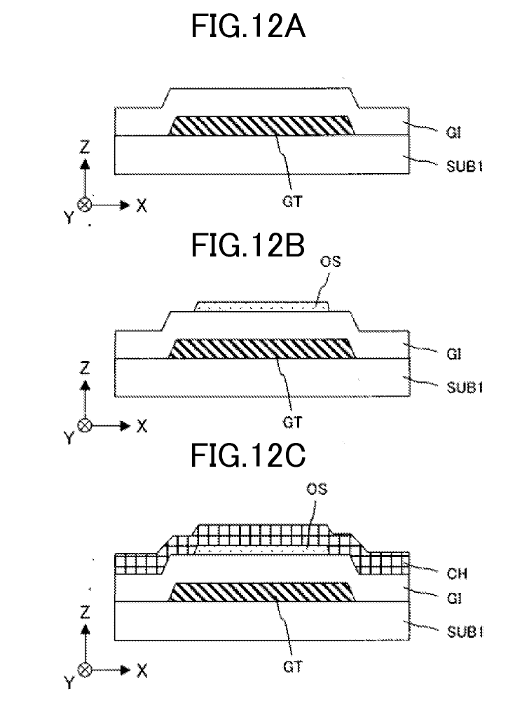

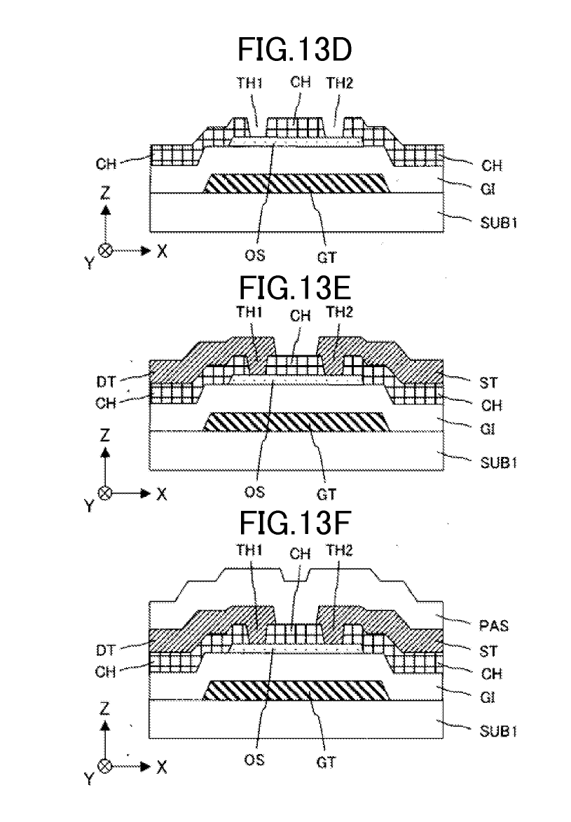

FIGS. 12A to 13F explain a method for manufacturing a thin film transistor of Embodiment 1 of the invention. Hereinafter, the method for manufacturing the oxide thin film transistor TFT of Embodiment 1 will be described based on FIGS. 12A to 13F. In the following description, however, since the thin film layers can be formed by a well-known photolithography technique, the detailed description of the forming method is omitted. Moreover, in the following description, a case will be described in which the oxide thin film transistor TFT is formed on a surface of a glass substrate that is a transparent insulating substrate used as an insulating substrate (first substrate) SUB1. However, the oxide thin film transistor TFT can be formed also on a non-light-transmissive insulating substrate in similar steps. Further, cross-sectional views shown in FIGS. 12A to 13F correspond to the cross-sectional view shown in FIG. 1B.

### a) Formation of Gate Electrode Layer GT (FIG. 12A)

First, a metal conductive film such as a molybdenum film or an aluminum film is deposited on the surface of the first substrate SUB1 as a glass substrate by, for example, a well-known sputtering method or the like. Subsequently, a photosensitive resin film (not shown) is applied on the metal conductive film, and then, the photosensitive resin film is developed and patterned to form a resist pattern. Thereafter, the metal conductive film exposed through the resist pattern is removed by wet etching or dry etching, and then, the resist pattern is peeled off, so that a gate electrode GT is formed. The gate electrode GT is directly formed on the surface of the first substrate SUB1 composed of a glass substrate. However, for preventing the mixing of alkali ions or the like from the first substrate SUB1, a so-called under film composed of a well-known silicon nitride film or the like may be formed on the first substrate SUB1, and the gate electrode GT may be formed on a surface (upper layer) of the under film. Moreover, instead of a glass substrate, a well-known flexible substrate capable of withstanding a heating step of the oxide thin film transistor TFT may be used as the first substrate SUB1.

Next, the gate insulating film GI composed of a silicon oxide film, a silicon nitride film, a silicon oxynitride film, or the like is deposited on the first substrate SUB1 on which the gate electrode GT is formed, so as to cover the surface of the first substrate SUB1 and the gate electrode layer GT by a well-known plasma CVD (Chemical Vapor Deposition) method or the like.

### b) Formation of Oxide Semiconductor Layer OS (FIG. 12B)

An oxide semiconductor thin film such as an In—Ga—Zn—O-based, In—Al—Zn—O-based, In—Sn—Zn—O-based, In—Zn—O-based, In—Sn—O-based, Zn—O-based, or Sn—O-based oxide semiconductor thin film is deposited above the first substrate SUB1 on which the gate insulating film GI is formed, that is, on a surface of the gate insulating film GI formed in the previous step, by a well-known sputtering method or the like. Subsequently, a well-known photosensitive resin film is applied on the oxide semiconductor thin film, and then, the photosensitive resin film is developed and patterned to form a resist pattern. Thereafter, the oxide semiconductor exposed through the resist pattern is removed by well-known wet etching or the like, and then, the resist pattern is peeled off, so that the island-like oxide semiconductor layer OS is formed. Moreover, by subjecting the oxide semiconductor layer OS to well-known plasma treatment using oxygen or nitrous oxide, the oxide semiconductor layer OS with few oxygen defects can be formed.

### c) Formation of Channel Protective Layer CH (FIGS. 12C and 13D)

First, a silicon oxide film is deposited above the first substrate SUB1 above which the oxide semiconductor layer OS is formed, so as to cover the surface of the gate insulating film GI and the oxide semiconductor layer OS by a well-known plasma CVD method or the like to form the channel protective layer CH (FIG. 12C).

Next, a well-known photosensitive resin film is applied on the channel protective layer CH, and then, the photosensitive resin film is developed and patterned to form a resist pattern. Thereafter, the channel protective layer CH exposed through the resist pattern is removed by well-known dry etching, so that the surface of the oxide semiconductor layer OS is exposed. In this step, the first and second through-holes (contact holes) TH1 and TH2 that electrically connect the oxide semiconductor layer OS with the source electrode layer ST and the drain electrode layer DT (provide contact between the oxide semiconductor layer OS and the source and drain electrode layers ST and DT) via the channel protective layer CH are formed in the channel protective layer CH (FIG. 13D). After this dry etching step, the resist pattern is peeled off. Although not shown in the drawing, a through-hole (contact hole) (not shown) to the gate electrode GT may be formed before forming the source electrode ST and the drain electrode DT. d) Formation of source electrode layer ST and drain electrode layer DT (FIG. 13E)

A metal conductive film such as a molybdenum film or an aluminum film is deposited above the first substrate SUB1 by a well-known sputtering method. Due to this, the metal conductive film is formed so as to cover the surface of the channel protective layer CH, the first and second through-holes TH1 and TH2 formed in the channel protective layer CH, and the oxide semiconductor layer OS. Subsequently, a well-known photosensitive resin film is applied on the metal conductive film, and then, the photosensitive resin film is developed and patterned to form a resist pattern. Thereafter, the metal conductive film exposed through the resist pattern is removed by well-known wet etching or dry etching, and then, the resist pattern is peeled off, so that the source electrode layer ST and the drain electrode layer DT are formed. The conductive film for forming the source electrode layer ST and the drain electrode layer DT is not limited to a metal conductive film. Other conductive thin films such as a transparent conductive film may be used.

### e) Formation of Passivation Layer PAS (FIG. 13F)

An insulating film such as a well-known silicon oxide film, silicon nitride film, or silicon oxynitride film is deposited above the first substrate SUB1 above which the source electrode layer ST and the drain electrode layer DT are formed, so as to cover the surface of the channel protective layer CH, the source electrode layer ST, and the drain electrode layer DT by a well-known plasma CVD method or the like to form the passivation layer PAS. Thereafter, although not shown in the drawing, through-holes (contact holes) to the source electrode and the drain electrode are formed in the passivation layer PAS. Due to this, the oxide thin film transistor TFT of Embodiment 1 is formed.

As described above, in the method for manufacturing the oxide thin film transistor TFT of Embodiment 1, the oxide thin film transistor TFT can be manufactured by manufacturing steps similar to those of a related-art thin film transistor in which a semiconductor layer is formed of amorphous silicon (amorphous silicon thin film transistor). Accordingly, the oxide thin film transistor TFT can be manufactured at a production efficiency similar to that of the related-art amorphous silicon thin film transistor, so that it is possible to suppress an increase in production cost associated with the formation of the oxide thin film transistor TFT.

As has been described above, the oxide thin film transistor TFT of Embodiment 1 is formed as follows. The channel protective layer CH is formed on one oxide semiconductor layer OS that overlaps one gate electrode layer GT, and the plurality of first and second through-holes TH1 and TH2 that reach the oxide semiconductor layer OS are formed in the channel protective layer CH. With the use of one first electrode layer (the drain electrode layer DT) that is connected to the oxide semiconductor layer OS via the plurality of first through-holes TH1 and one second electrode layer (the source electrode layer ST) that is connected to the oxide semiconductor layer OS via the second through-holes TH2, one oxide thin film transistor TFT that is formed of the plurality of unit thin film transistors TU connected in parallel and whose channel width is the opening widths of the first and second through-holes TH1 and TH2 in the parallel arrangement direction thereof is formed.

Accordingly, the channel width W that is needed when forming the oxide thin film transistor TFT having a needed drive capability can by formed using the total channel width W of the plurality of unit thin film transistors TU that form one oxide thin film transistor TFT. Therefore, it is possible to suppress fluctuations in the threshold voltage Vth in the oxide thin film transistor TFT caused by the size of the channel width W, so that even when a circuit is configured using a plurality of oxide thin film transistors TFT having different channel widths, the circuit can normally operate.

That is, as has been described above in the section of “advantageous effect”, the total width W=W1+W2+ . . . +Wn, which is the sum of the channel widths W1, W2, . . . , and Wn of the unit thin film transistors TU that form one thin film transistor TFT, is the substantial channel width W of the oxide thin film transistor TFT of Embodiment 1. Accordingly, in the oxide thin film transistor TFT of Embodiment 1 having the channel width W, a drive capability corresponding to the channel width W is provided, and one oxide thin film transistor is formed of the n unit thin film transistors TU. As a result, even when a circuit is configured using a mix of an oxide thin film transistor TFT that needs a great drive capability and a thin film transistor TFT of a relatively low drive capability, the threshold voltage Vth of each of the oxide thin film transistors TFT can be made substantially constant, and therefore, a circuit can normally operate.

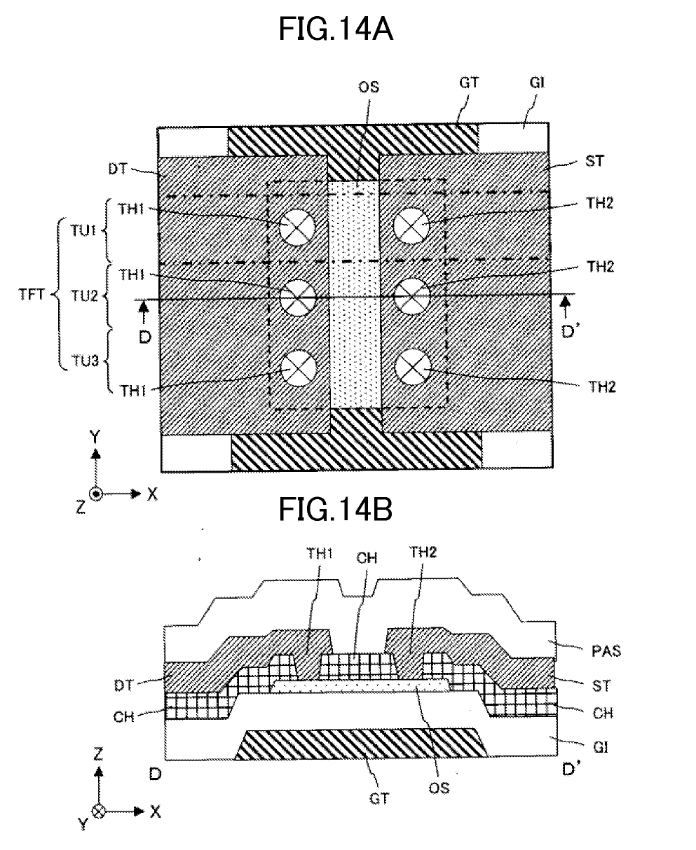

In the oxide thin film transistor TFT of Embodiment 1, a case has been described in which the first and second through-holes TH1 and TH2 are square. However, as shown in FIG. 14A, in the shape of the first and second through-holes TH1 and TH2, corners are rounded in some cases in relation to an etching stopper or processing accuracy. However, as shown in FIG. 14B, which is a cross-sectional view taken along the line D-D′ in FIG. 14A, the configuration of the thin film layers is the same as that shown in FIG. 1B, and therefore, the advantageous effect described above can be obtained.

### Embodiment 2

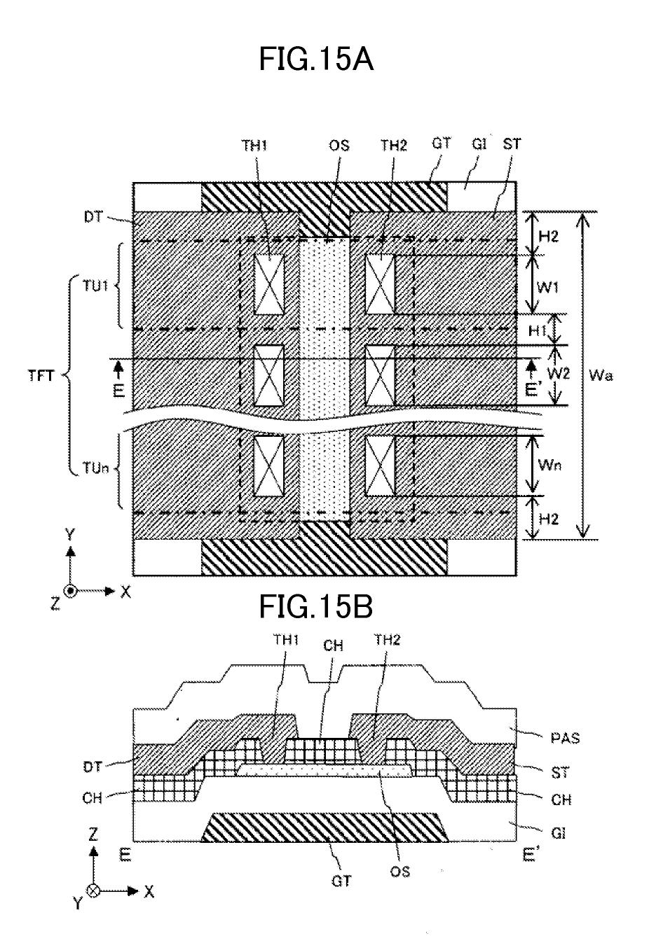

FIGS. 15A and 15B explain a schematic configuration of a thin film transistor of Embodiment 2 of the invention, in which FIG. 15A is a plan view of the oxide thin film transistor of Embodiment 2; and FIG. 15B is a cross-sectional view taken along the line E-E′ shown in FIG. 15A. The oxide thin film transistor TFT of Embodiment 2 differs from that of Embodiment 1 only in the opening width of the first and second through-holes TH1 and TH2 in the Y-direction (channel width direction), that is, the channel width of the unit thin film transistor TU, and the other configurations are similar to those of Embodiment 1. Accordingly, in the following description, configurations relating to the channel width of the unit thin film transistor TU will be described in detail.

As is apparent from FIG. 15A, the oxide thin film transistor TFT of Embodiment 2 is formed such that the channel widths W1 to Wn of the unit thin film transistors TU1 to TUn in the Y-direction (channel width direction) are the same, and that each of the channel widths W1 to Wn is larger than that of the unit thin film transistor TU of Embodiment 1.

That is, in the configuration of the unit thin film transistors TU1 to TUn of Embodiment 2, the opening width of the first through-hole TH1 and the second through-hole TH2 that are formed in the channel protective layer CH is different in size between the Y-direction (channel width direction) and the X-direction (channel length direction). Also in the oxide thin film transistor TFT of Embodiment 2 having this configuration, as is apparent from FIG. 15B, the gate electrode layer GT, the gate insulating film GI, the oxide semiconductor layer OS, the channel protective layer CH, the drain electrode layer DT and the source electrode layer ST, and the passivation layer PAS are stacked in this order from the insulating substrate (not shown) side on the lower side in the drawing. Regions of the oxide semiconductor layer OS exposed through the opening portions of the first through-hole TH1 and the second through-hole TH2 that are formed in the channel protective layer CH serve as contact regions, and a channel region is formed in a region between the contact regions. Accordingly, also in the configuration of the oxide thin film transistor TFT of Embodiment 2, similarly to the oxide thin film transistor of Embodiment 1, the opening widths W1 to Wn of the first through-holes TH1 and the second through-holes TH2 in the Y-direction (channel width direction) that are formed in the channel protective layer CH are the channel widths W1 to Wn of the unit thin film transistors TU1 to TUn. Therefore, advantageous effects similar to those of the oxide thin film transistor TFT of Embodiment 1 can be obtained.

Further, the oxide thin film transistor TFT of Embodiment 2 is formed of the unit thin film transistors TU1 to TUn in which the opening widths (corresponding to the channel widths) W1 to Wn of the first through-holes TH1 and the second through-holes TH2 are larger than those of the unit thin film transistors TU that form the oxide thin film transistor of Embodiment 1. Accordingly, the amount of current that one unit thin film transistor TU can flow can be increased, so that the oxide thin film transistor TFT having the same drive capability can be formed of a smaller number of unit thin film transistors TU than the number of those in Embodiment 1. As a result, a region formed between adjacent unit thin film transistors TU can be reduced. Especially when, for example, a larger amount of current needs to be obtained, it is possible to obtain a special advantageous effect that the size of the oxide thin film transistor TFT can be reduced.

However, as shown in the section of “advantageous effect” of Embodiment 1 described above, when the channel width of an oxide thin film transistor is increased, the threshold voltage Vth is shifted in the negative direction. On the other hand, for enhancing the drive capability to obtain a large amount of current and making the transistor size of the oxide thin film transistor TFT as small as possible, the channel widths W1 to Wn of the unit thin film transistors TU1 to TUn are preferably formed large. As to the effect of preventing the shift of the threshold voltage Vth in the negative direction, the configuration shown in Embodiment 1 described above exhibits a greater effect.

Accordingly, in the following description, the opening width of the first through-hole TH1 and the second through-hole TH2 in the Y-direction (channel width direction) within a range that the shift of the threshold voltage Vth can be allowed will be described in detail.

First, a case will be described in which in the oxide thin film transistor TFT of Embodiment 2 shown in FIGS. 15A and 15B, an oxide thin film transistor TFT whose total width W (=W1+W2+ . . . +Wn) of the opening widths W1 to Wn of n unit thin film transistors TU1 to TUn for obtaining necessary current is 50 RI in the Y-direction (channel width direction) is formed. A width Wa of the drain electrode layer DT and the source electrode layer ST of the oxide thin film transistor TFT in the Y-direction (channel width direction) is defined as the transistor size of the oxide thin film transistor TFT for convenience sake. Moreover, the opening widths W1 to Wn of the first through-holes TH1 and the second through-holes TH2 in the Y-direction (channel width direction) are the same, that is, W1=W2= . . . =Wn.

The adjacent gap H1 in the Y-direction between the adjacent first through-holes TH1 and between the adjacent second through-holes TH2 is 3 μm. A length H2 from an opening edge (upper opening edge in FIG. 15A) of the second through-hole TH2 of the unit thin film transistor TU1 formed on the side of the edge in the Y-direction to an edge side of the source electrode layer ST is 3 μm at a minimum (H2≧3 μm). Similarly, a length H2 from an opening edge (lower opening edge in FIG. 15A) of the second through-hole TH2 of the unit thin film transistor TUn to an edge side of the source electrode layer ST is also 3 μm at a minimum. Further, the remaining length is adjusted by setting H2 to be 3 μm or more.

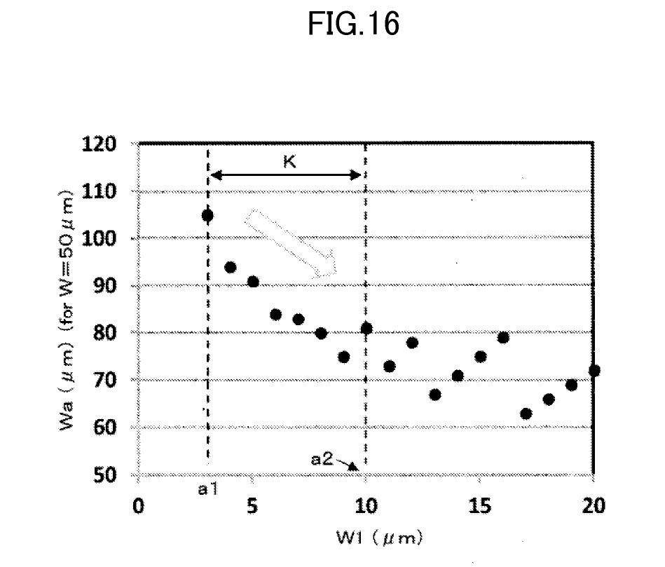

As is apparent from FIG. 16, which shows the transistor size Wa in the channel width direction when successively changing the opening width W1 of the second through-hole TH2 (including the first through-hole TH1) of a predetermined number of unit thin film transistors TU, it is found that when the opening width of the second through-hole TH2 (the opening width of the first through-hole TH1 is also the same) is widened from 3 μm that is indicated by al, the width Wa that is needed for obtaining W=50 μm is reduced. It is apparent from this result that when the opening width (W1 to Wn) of the first through-hole TH1 and the second through-hole TH2 of the unit thin film transistor TU is changed, the transistor size Wa of the oxide thin film transistor TFT of the invention in the channel width direction can be reduced. The transistor size in the channel length direction (the X-direction) is similar to that of the related-art oxide thin film transistor.

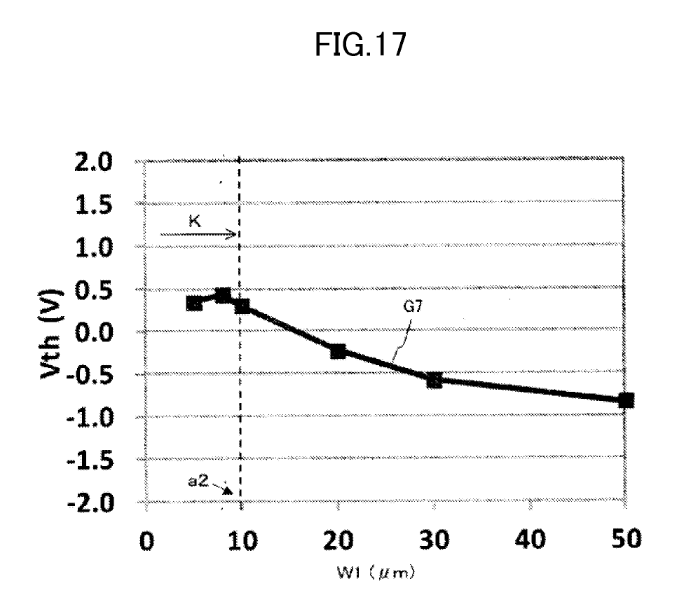

FIG. 17 shows a relationship between the opening width W1 (corresponding to the channel width) of the second through-hole TH2 of the unit thin film transistor TU and the threshold voltage Vth. Hereinafter, a relationship between the threshold voltage Vth and the channel width corresponding to the opening width of the first through-hole TH1 and the second through-hole TH2 in the unit thin film transistor TU will be studied based on FIG. 17. FIG. 17 is obtained by enlarging FIG. 9 in the channel width direction, and therefore, the line G7 is also obtained by enlarging the line G4 in the channel width direction.

As is apparent from FIG. 17, when the opening width W1 (corresponding to the channel width) of the second through-hole TH2 falls within a range K of 10 μm or less, which is indicated by a2, the threshold voltage Vth indicated by the line 7 is substantially constant at about 0.7V (volt). On the other hand, when the opening width W1 (corresponding to the channel width) of the second through-hole TH2 is 10 μm or more, the threshold voltage Vth is shifted in the negative direction in proportion to the size of the opening width W1. Accordingly, the opening widths W1 to Wn of the first through-holes TH1 and the second through-holes TH2, each of which corresponds to the channel width, are each preferably 10 μm or less. That is, by forming the unit thin film transistors TU in which the opening widths W1 to Wn of the first through-holes TH1 and the second through-holes TH2 are each 10 μm or less, the shift of the threshold voltage Vth can fall within an allowable range. Therefore, advantageous effects similar to those of Embodiment 1 described above can be obtained.

Each of the adjacent gaps between the first through-holes TH1 and between the second through-holes TH2 described above or the minimum length from the first through-hole TH1 and the second through-hole TH2 to the electrode edge is set to be 3 μm. However, even when the gap or length is 4 μm, the tendency of the result does not change. Moreover, the sum W of opening widths of the first through-holes TH1 and the second through-holes TH2 in the channel width direction is not limited to 50 μm. Even when W=100 μm, 200 μm, or the like, the tendency of the result does not change.

On the other hand, the adjacent gap H1 between the unit thin film transistors TU, which causes the shift of the threshold voltage Vth in the negative direction, depends also on the opening widths W1 to Wn of the first and second through-holes TH1 and TH2. That is, for obtaining a favorable threshold voltage Vth when each of the opening widths W1 to Wn of the first and second through-holes TH1 and TH2 is as large (long) as 10 μm, the gap needs to be provided such that the adjacent gap H1 is at least 3 μm or more. That is, a gap of 1.5 μm or more is preferably provided on both sides of each of the first through-hole TH1 and the second through-hole TH2 in the adjacent direction.

However, when the gap between the adjacent unit thin film transistors TU is widened, the transistor size of the oxide thin film transistor TFT is increased. Accordingly, it is sufficient that each of the adjacent gaps H1 between the first through-holes TH1 and between the second through-holes TH2 that form the adjacent unit thin film transistors TU is 4 μm at most.

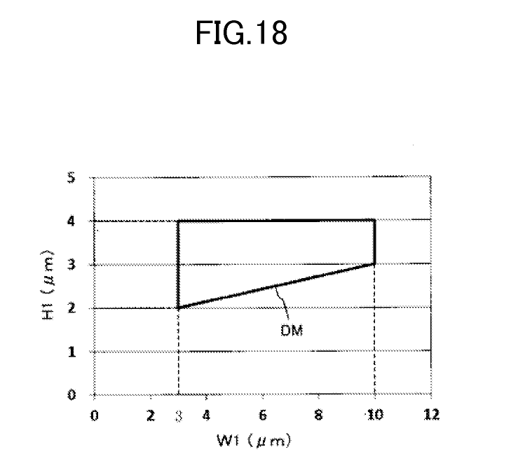

As a result, as shown in FIG. 18 in which the horizontal axis represents the opening widths W1 to Wn of the first through-holes TH1 and the second through-holes TH2 of the unit thin film transistors TU while the vertical axis represents the adjacent gap H1, the opening widths W1 to Wn and the adjacent gap H1 are preferably determined so as to fall within a range of a region DM indicated by the heavy lines. That is, the opening widths W1 to Wn and the adjacent gap H1 are preferably determined so as to fall within the range of the region DM surrounded by Expression 1 to Expression 4 in FIG. 18.

H1=W1/7+1.57 μm Expression 1

H1=4 μm Expression 2

W1=10 μm Expression 3

W1=4 μm Expression 4

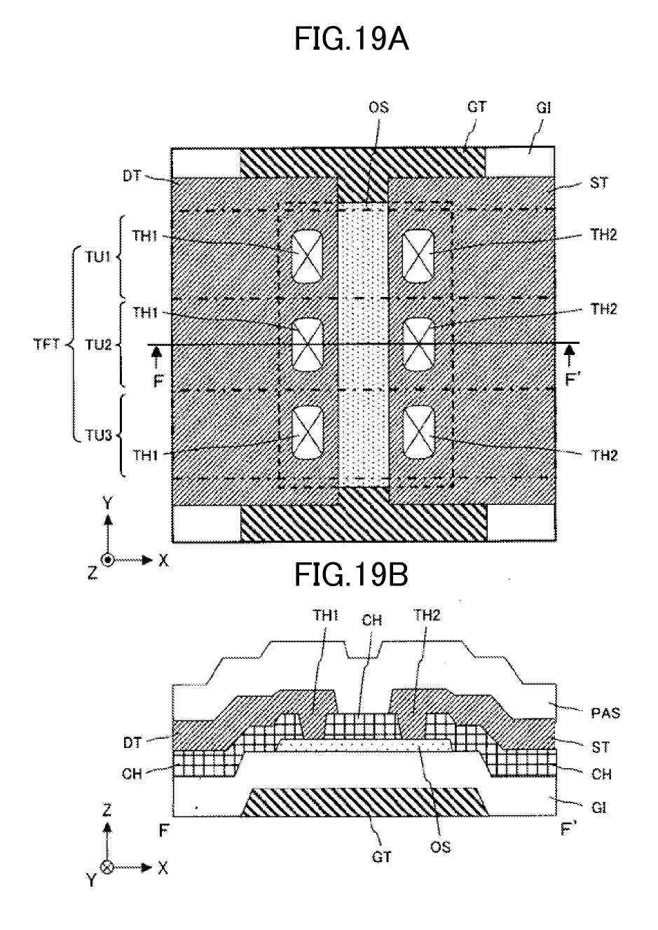

In the oxide thin film transistor TFT of Embodiment 2, a case has been described in which the first and second through-holes TH1 and TH2 are rectangular. However, as shown in FIG. 19A, in the shape of the first and second through-holes TH1 and TH2, corners are rounded in some cases in relation to an etching stopper or processing accuracy. However, as shown in FIG. 19B, which is across-sectional view taken along the line F-F′ in FIG. 19A, the configuration of the thin film layers is the same as that shown in FIG. 15B, and therefore, the advantageous effects described above can be obtained.

### Embodiment 3

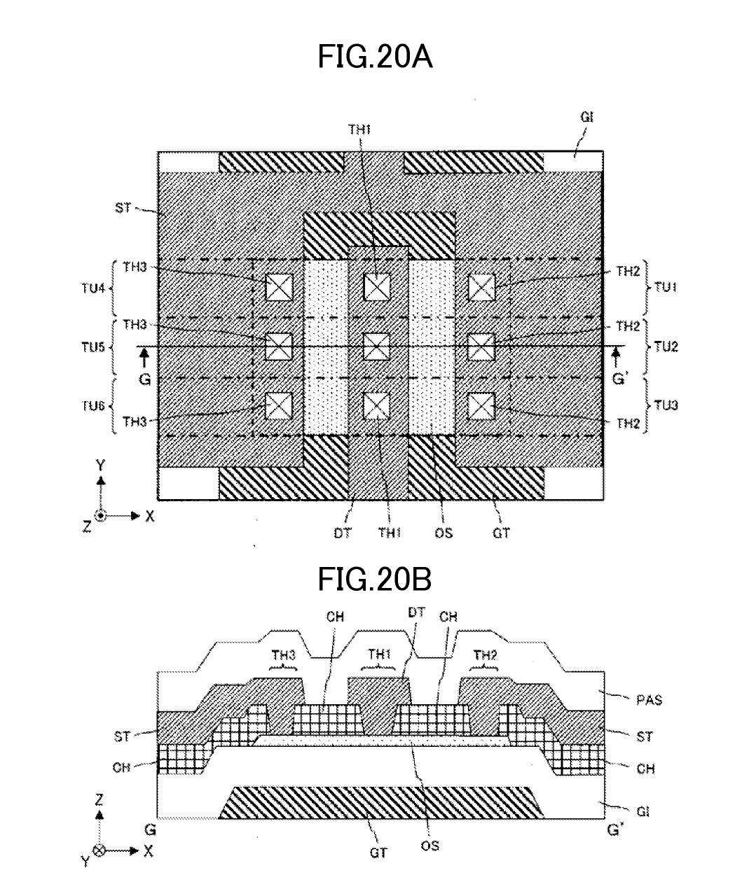

FIGS. 20A and 20B explain a schematic configuration of a thin film transistor of Embodiment 3 of the invention, in which FIG. 20A is a top view of the oxide thin film transistor of Embodiment 3; and FIG. 20B is a cross-sectional view taken along the line G-G′ shown in FIG. 20A. The oxide thin film transistor TFT of Embodiment 3 differs from that of Embodiment 1 only in the forming positions of unit thin film transistors TU4 to TU6, and the other configurations are the same as those of Embodiment 1. Accordingly, in the following description, the unit thin film transistors TU4 to TU6 will be described in detail.

As is apparent from FIG. 20A, the oxide thin film transistor TFT of Embodiment 3 has a structure in which the source electrode layer ST is arranged on both sides relative to the drain electrode layer DT. Specifically, in the oxide thin film transistor TFT of Embodiment 3, the drain electrode layer DT is formed so as to cover the first through-holes TH1 that are arranged in parallel in the Y-direction at the center in the drawing and reach the oxide semiconductor layer OS. The drain electrode layer DT is electrically connected to regions (serving as contact regions) of the oxide semiconductor layer OS exposed through the first through-holes TH1. The source electrode layer ST is formed so as to cover the second through-holes TH2 and third through-holes TH3 that are arranged in parallel in the Y-direction on the left and right in the drawing and reach the oxide semiconductor layer OS. The source electrode layer ST is electrically connected to regions (serving as contact regions) of the oxide semiconductor layer OS exposed through the second through-holes TH2 and the third through-holes TH3.

In the oxide thin film transistor TFT of Embodiment 3 having this configuration, as shown in FIG. 20B, the gate electrode layer GT is arranged on the side below the oxide semiconductor layer OS via the gate insulating film GI. Further, the first through-hole TH1 and the second through-hole TH2 are arranged to face each other via the oxide semiconductor layer OS, and a channel region is formed in a region between the first through-hole TH1 and the second through-hole TH2. Also, the first through-hole TH1 and the third through-hole TH3 are arranged to face each other, and a channel region is also formed in a region between the first through-hole TH1 and the third through-hole TH3. Therefore, the unit thin film transistors TU1 to TU6 that are formed, in the drawing, to the left and right of the drain electrode layer DT connected to the oxide semiconductor layer OS via the first through-holes TH1 are arranged in parallel and connected. As a result, also in the configuration of the oxide thin film transistor TFT of Embodiment 3, advantageous effects similar to those of Embodiment 1 can be obtained.

In this case, in the configuration of Embodiment 3, a group of the unit thin film transistors TU1 to TU3 that are arranged in parallel in the channel width direction of the oxide thin film transistor TFT and a group of the unit thin film transistors TU4 to TU6 that are arranged in parallel in the channel width direction are arranged in parallel in the channel length direction. That is, the plurality of unit thin film transistors TU1 to TU6 that form one oxide thin film transistor TFT are arranged in an in-plane direction (the X-direction and the Y-direction) of the insulating substrate (not shown). Accordingly, it is possible to obtain a special advantageous effect that the outer shape of the oxide thin film transistor TFT can be easily conformed to the shape of a forming region.

Especially in the configuration of the oxide thin film transistor TFT of Embodiment 3, the first through-hole TH1 (contact region) for electrically connecting the drain electrode layer DT with the oxide semiconductor layer OS is commonly used between the unit thin film transistor TU1 and the unit thin film transistor TU4 that are arranged in parallel in the channel length direction, between the unit thin film transistor TU2 and the unit thin film transistor TU5 that are arranged in parallel in the channel length direction, and between the unit thin film transistor TU3 and the unit thin film transistor TU6 that are arranged in parallel in the channel length direction. As a result, even when the unit thin film transistors TU are arranged in parallel in the channel length direction, an increase in transistor size can be minimized in the channel length direction.

In the configuration of the oxide thin film transistor TFT of Embodiment 3, three unit thin film transistors TU are arranged in parallel in the Y-direction. However, it is sufficient that one or more unit thin film transistors are provided. Moreover, the number of unit thin film transistors TU arranged in parallel in the X-direction is not limited to two shown in FIGS. 20A and 20B, but may be three or more. In this case, for example, each of the drain electrode layer DT and the source electrode layer ST is formed into a comb-teeth shape, and a through-hole is formed in each of the comb-teeth shape portions, so that the unit thin film transistor TU can be formed.

Also in the oxide thin film transistor TFT of Embodiment 3, even when corners of the first to third through-holes TH1 to TH3 are rounded, the advantageous effects described above can be obtained similarly to Embodiment 1 and Embodiment 2.

### Embodiment 4

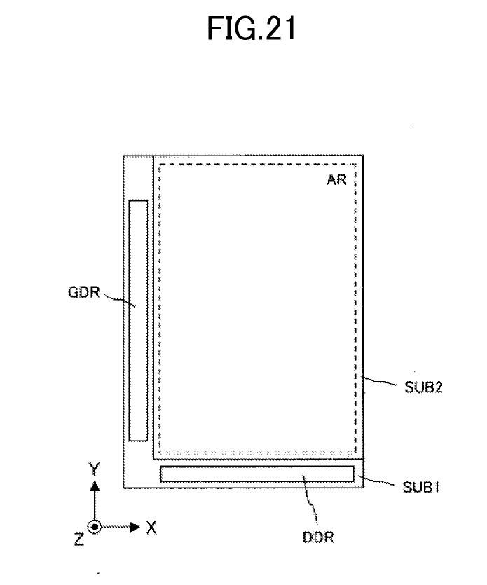

FIG. 21 is a plan view for explaining a schematic configuration of a liquid crystal display device as a display device of Embodiment 4 of the invention. The display device is obtained by applying the oxide thin film transistor TFT of the invention to switching thin film transistors for a driver circuit and a pixel. In the following description, a case will be described in which the oxide thin film transistor TFT of Embodiment 1 is applied to a liquid crystal display device. However, the oxide thin film transistor TFT of Embodiment 2 or 3 is also applicable in the same manner. Moreover, the oxide thin film transistor TFT of the invention can be applied to other display devices such as an organic EL display device or other electronic devices in which the oxide thin film transistor TFT is formed on an insulating substrate.

In the following description, a case will be described in which the thin film transistor of the invention is applied to an IPS type liquid crystal display device. However, the thin film transistor of the invention can also be applied in the same manner to a liquid crystal display device of other types such as a TN type or a VA type.

As shown in FIG. 21, the liquid crystal display device of Embodiment 4 includes the first substrate SUB1 and a second substrate SUB2 that are arranged to face each other via a liquid crystal layer (not shown). The first substrate SUB1 is composed of a transparent insulating substrate on which thin film transistors, well-known pixel electrodes, and the like (all not shown) are formed. The second substrate SUB2 is composed of a transparent substrate on which color filters and the like are formed. The first substrate SUB1 and the second substrate SUB2 are fixed together with a sealing material (not shown) applied along an edge portion of the second substrate SUB2, and liquid crystal is sealed therebetween.

Scanning signal lines (gate lines) (not shown) extending in the X-direction and arranged in parallel in the Y-direction and video signal lines (drain lines) (not shown) extending in the Y-direction and arranged in parallel in the X-direction are formed on a liquid crystal surface side of the first substrate SUB1. A pixel region is formed in each of regions surrounded by the scanning signal lines and the video signal lines. Pixels are arranged in a matrix in a display area AR. In each of the pixels, the above-described oxide thin film transistor for switching and a pixel electrode (not shown) are formed on the first substrate SUB1. Similarly to a related-art liquid crystal display device, the switching oxide thin film transistor is turned on or off in synchronization with a scanning signal input from the gate line, while a video signal from the drain line DL is output to the pixel electrode.

In the display device of Embodiment 4, a scanning signal line driver circuit (gate line driver circuit) GDR and a video signal line driver circuit (drain line driver circuit) DDR are formed in a so-called picture-frame region as a region between the edge of the first substrate SUB1 and the display area AR. The gate line driver circuit GDR generates a scanning signal based on an external control signal and outputs the scanning signal to the gate line. The drain line driver circuit DDR generates a video signal and outputs the video signal to the drain line. In this case, in the display device of Embodiment 4, the gate line driver circuit GDR and the drain line driver circuit DDR are composed of the above-described oxide thin film transistors formed on the first substrate SUB1 as a transparent insulating substrate.

Accordingly, it becomes possible to prevent fluctuations in threshold voltage in the oxide thin film transistors constituting the gate line driver circuit GDR and the drain line driver circuit DDR, which eliminates the need for a circuit or the like for compensating the fluctuations in the threshold voltage. Therefore, the picture-frame region can be narrowed. That is, even when the glass substrate having the same outer shape is used, the display area AR can be widened. Moreover, since the management of the threshold voltage of the thin film transistors constituting the gate line driver circuit GDR and the drain line driver circuit DDR can be made easy or unnecessary, product variations in display device can be suppressed low. Therefore, the reliability of the display device of Embodiment 4 can be improved.

As described above, the method for manufacturing the oxide thin film transistor of the invention is similar to that of a related-art amorphous silicon thin film transistor. Accordingly, the display device of Embodiment 4, which is a display device using the oxide thin film transistor of the invention, can be manufactured by a manufacturing method similar to that of a related-art display device using an amorphous silicon thin film transistor. Therefore, it is possible to obtain a special advantageous effect that the display device using the oxide thin film transistor can be manufactured without greatly changing the manufacturing steps of the display device. Moreover, since the display device of Embodiment 4 can be manufactured by the manufacturing method similar to that of the related-art display device using an amorphous silicon thin film transistor, it is possible to obtain a special advantageous effect that the display device using the oxide thin film transistor can be manufactured at a production efficiency similar to that of the related-art display device using an amorphous silicon thin film transistor.

Further, since the switching thin film transistor for a pixel is formed of an oxide thin film transistor with high mobility, the occupied area of the oxide thin film transistor occupying the pixel region can be reduced, and also the aperture ratio can be improved.

Still further, since the gate line driver circuit GDR and the drain line driver circuit DDR are also formed of oxide thin film transistors, it become easy to improve the reliability of the liquid crystal display device and realize high mobility. That is, a thin film transistor having a great drive capability can be formed even with the same occupied area as that of an amorphous silicon thin film transistor. Accordingly, when a driver circuit or the like is formed using the oxide thin film transistor TFT of Embodiment 1, it is possible to obtain an advantageous effect that the area for forming the driver circuit can be reduced.

Further, a circuit for compensating the shift of the threshold voltage Vth, which is needed when using a related-art oxide thin film transistor, can be made unnecessary. Accordingly, it is possible to obtain a special advantageous effect that the driver circuit area can be reduced and power consumption can also be reduced.

In the display device of Embodiment 4, the gate line driver circuit GDR and the drain line driver circuit DDR are formed in different side portions of the first substrate SUB1. However, the gate line driver circuit GDR and the drain line driver circuit DDR may be formed in the same side portion.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A thin film transistor comprising:
an oxide semiconductor layer that is formed above a gate electrode layer via a first insulating film; and
a drain electrode layer and a source electrode layer that are formed above the oxide semiconductor layer via a second insulating film, wherein
the drain electrode layer and the source electrode layer are electrically connected with the oxide semiconductor layer via through-holes formed in the second insulating film arranged between the drain and source electrode layers and the oxide semiconductor layer,
the drain electrode layer and the source electrode layer are formed over opposite edge portions of the oxide semiconductor layer,
a channel region is formed in a region of the oxide semiconductor layer between the drain electrode layer and the source electrode layer that are electrically connected with the oxide semiconductor layer via the through-holes,
a first through-hole that electrically connects the drain electrode layer with the oxide semiconductor layer and a second through-hole that electrically connects the source electrode layer with the oxide semiconductor layer each include two or more through-holes that are arranged in parallel in a channel width direction of the thin film transistor, and
a total width of opening widths of the first through-holes or the second through-holes in the channel width direction is a channel width of the thin film transistor.

2. The thin film transistor according to claim 1, wherein
the numbers of the first through-holes and the second through-holes are the same,
opening widths of the first through-hole and the second through-hole in a direction in which the first and second through-holes are arranged in parallel are substantially the same, and
gaps each between the first through-hole and the second through-hole adjacent to each other are substantially the same.

3. The thin film transistor according to claim 2, wherein
a gap between the first through-holes adjacent to each other in the channel width direction is substantially the same as that of the second through-holes.

4. The thin film transistor according to claim 1, wherein
when a gap between the first through-holes adjacent to each other and between the second through-holes adjacent to each other is H1, the gap H1 between the adjacent through-holes satisfies a relationship of H1≧2 μm.

5. The thin film transistor according to claim 1, wherein
when the opening width of the first through-hole and the second through-hole in the channel width direction is W1, and a gap between the first through-holes adjacent to each other and between the second through-holes adjacent to each other is H1, the opening width W1 satisfies a relationship of 10 μm≧W1≧3 μm, and
the gap H1 between the adjacent through-holes satisfies a relationship of 4 μm≧H1≧2 μm.

6. The thin film transistor according to claim 1, wherein
the oxide semiconductor layer includes a plurality of contact regions corresponding respectively to opening regions of a plurality of the first through-holes and a plurality of the second through-holes, and
the drain electrode layer and the source electrode layer are electrically connected with the oxide semiconductor layer at the plurality of contact regions.

7. A display device comprising a first substrate,
the first substrate including, formed thereon,
scanning signal lines that extend in an X-direction and are arranged in parallel in a Y-direction and to which a scanning signal is input,
video signal lines that extend in the Y-direction and are arranged in parallel in the X-direction and to which a video signal is input,
switching thin film transistors each of which is arranged in the vicinity of an intersection between the scanning signal line and the video signal line and controls reading of the video signal in synchronization with the scanning signal, and
a driver circuit that generates the scanning signal or/and the video signal, wherein
at least the driver circuit is formed of the thin film transistor according to claim 1, and
the thin film transistor includes two or more thin film transistors in which at least the numbers of the first through-holes are different from each other and whose drive capabilities are different from each other.

8. The display device according to claim 7, wherein
the switching thin film transistor is formed of the thin film transistor.
